(19) United States
(12) Patent Application Publication
(10) Pub. No.: US 2013/0222047 A1
(43) Pub. Date: Aug. 29, 2013

(54) DRIVING METHOD FOR CHARGER NOISE REJECTION IN TOUCH PANEL

(71) Applicants: Jung-Shou HUANG, Hsinchu County (TW); Chia-Mu Wu, Taipei City (TW); Tse-Lun Hung, Taipei City (TW); Shun-Yi Chen, Taoyuan County (TW)

(72) Inventors: Jung-Shou HUANG, Hsinchu County (TW); Chia-Mu Wu, Taipei City (TW); Tse-Lun Hung, Taipei City (TW); Shun-Yi Chen, Taoyuan County (TW)

(73) Assignee: ELAN MICROELECTRONICS CORPORATION, Hsin Chu (TW)

(21) Appl. No.: 13/550,090

(22) Filed: Jul. 16, 2012

(30) Foreign Application Priority Data
Feb. 24, 2012 (TW) 101106189

(51) Int. Cl. H03K 17/96

(52) U.S. Cl. 327/517

(57) ABSTRACT

A driving method for charger noise rejection in a touch panel has steps of: reading the sensing frame of the touch panel with a self-capacitance sensing mode, marking at least one first-axis sensing line having a recognizable sensing value, and driving the at least one marked first-axis sensing line with a mutual-capacitance sensing mode to acquire at least one sensing value corresponding to at least one sensing point on each one of the at least one marked first-axis sensing line. Accordingly, the charger noise is rejected in the touch panel by the driving method of the present invention. Additionally, a frame rate is further increased since the sensing lines are partially driven under the mutual-capacitance sensing mode.

### BACKGROUND OF THE INVENTION

1. Field of the Invention

The present invention relates to a driving method for charger noise rejection in a touch panel and more particularly to a driving method using mixed sensing modes to effectively eliminate charger noise and further enhance a frame rate of a capacitive touch panel.

2. Description of the Related Art

Since the advent of smart phones, capacitive touch panels have become an indispensable part of the smart phones. With reference to FIG. 6, a conventional capacitive touch panel has a substrate 80, multiple X-axis electrodes 81, multiple Y-axis electrodes 82, multiple coupling capacitors Cp and a transparent panel 83. The X-axis electrodes 81 and the Y-axis electrodes 82 are alternately formed on the substrate 80. Each coupling capacitor Cp is formed between one of the X-axis electrodes 81 and one of the Y-axis electrodes 82 adjacent to each other. The transparent panel 83 is mounted on the X-axis electrodes 81 and the Y-axis electrodes 82. With reference to FIG. 7, when a finger or a conductive object contacts the transparent panel 83 and approaches a corresponding X-axis electrode 81 and Y-axis electrode 82, a new capacitor Cf is formed in addition to a corresponding coupling capacitor Cp as the finger or the conductive object is conductive. Hence, when a controller reads a capacitive value between the corresponding X-axis electrode 81 and Y-axis electrode 82 associated with the touch position through X-axis sensing lines and Y-axis sensing lines (not shown), variation of a capacitive value determines if a position having the capacitive value is touched. As to how the variation of capacitive value is determined, typically, a mutual capacitance sensing mode and a self capacitance sensing mode are employed. The mutual capacitance sensing mode is performed by outputting excitation signals through the Y-axis sensing lines and receiving raw data of ADC (analog-to-digital converter) through the X-axis sensing lines. With reference to FIG. 8, as the coupling capacitor Cp and the dynamically formed capacitor Cf of a touched position are serially connected when a finger touches the position to form the new capacitor Cf, the ADC raw data are thus attenuated and the controller can detect variation of the capacitive value and determine if the coordinates of the touched position need to be reported.

However, during the course of operation, touch panels are prone to noise interference resulting from many environmental factors. For instance, when touch panels are applied to mobile phones, the likelihood is that the mobile phones are sensitive to interferences originating from various sources in operation. Smart phones normally consume more power attributable to their versatile functionality and oftentimes need to be recharged. Depending on the type of a charger in use, it is more likely than not that an operating mobile phone connected with the charger is subject to noise interference when the charger is a source of high noise interference and the mobile phone and a user thereof both stay in a floating state. The noise interference results in detectable capacitance values at untouched positions. The capacitance values at the untouched positions are treated as peak values, and the peak values are reported.

With reference to FIG. 9, a conventional sensing frame is read by a mutual capacitance sensing mode. Each Y-axis sensing line of the conventional sensing frame outputs excitation signals, and corresponding X-axis sensing lines receive analog sensing signals. When a finger touches the conventional sensing frame as shown on the right side of FIG. 9, the untouched position shows detectable capacitance value, and a corresponding X-axis sensing line receives an analog sensing signal. The analog sensing signal is converted into a sensing value, and coordinate corresponding to the sensing value are reported. When a mobile phone is being operated and charged and both the mobile phone and the user are in the floating state, detectable capacitance values appear at the positions untouched by the finger as shown on the left side of FIG. 9, the coordinates of those untouched positions are mistakenly reported.

### SUMMARY OF THE INVENTION

An objective of the present invention is to provide a driving method using mixed sensing modes to effectively eliminate charger noise and further enhance a frame rate of a capacitive touch panel.

To achieve the foregoing objective, the driving method has steps of:

reading the sensing frame of the touch panel with a self-capacitance sensing mode, and marking at least one first-axis sensing line, wherein each one of the at least one marked first-axis sensing line has a recognizable sensing value; and

driving the at least one marked first-axis sensing line with a mutual-capacitance sensing mode to acquire at least one sensing value corresponding to at least one sensing point on each one of the at least one marked first-axis sensing line.

Preferably, the driving method further has steps of:

setting up a parameter set under the self-capacitance sensing mode;

determining if the sensing value of each sensing point on each one of the at least one marked first-axis sensing line acquired under the mutual-capacitance sensing mode is a peak value;

determining if the sensing value acquired under the self-capacitance sensing mode of each sensing point having the peak value complies with the parameter set; and

if the sensing value acquired under the self-capacitance sensing mode of each sensing point having the peak value does not comply with the parameter set, rejecting the sensing point having the peak value.

The above-mentioned driving method employs mixed sensing modes, namely a self-capacitance sensing mode and a mutual-capacitance sensing mode. The self-capacitance sensing mode is employed to identify each sensing line having a recognizable sensing value, and the mutual-capacitance sensing mode is employed to partially drive the sensing lines identified by the self-capacitance sensing mode. As the self-capacitance sensing mode is good at its anti-interference capability against charger noise, the sensing values caused by charger noise are not easy to be mistakenly acquired. In other words, each sensing line having the recognizable sensing value and acquired by the self-capacitance sensing mode has already been immune to the interference caused by charger noise. Hence, when the mutual-capacitance sensing mode is further employed to read the sensing frame, only the sensing lines filtered by the self-capacitance sensing mode are driven, thereby avoiding the false report of the coordinates of the sensing points having the sensing values caused by charger noise. Due to the sensing lines partially driven under the mutual-capacitance sensing mode, a frame rate of the touch panel is increased.

After mutual-capacitance sensing mode is employed to drive the marked sensing lines only to acquire the sensing points having the recognizable sensing values, the sensing values of the sensing points acquired under the self-capacitance sensing mode are compared with the parameter set configured under the self-capacitance sensing mode. If the sensing values of the sensing points acquired under the self-capacitance sensing mode do not comply with the condition set up in the parameter set, the sensing values of the sensing points are rejected.

The foregoing driving method can further distinguish the sensing values of the sensing points touched by a finger and caused by charger noise on the same sensing line to avoid the false report of the coordinates of the sensing points having the sensing values caused by charger noise.

Other objectives, advantages and novel features of the invention will become more apparent from the following detailed description when taken in conjunction with the accompanying drawings.

### BRIEF DESCRIPTION OF THE DRAWINGS

FIG. 1 is a flow chart of a first embodiment of a driving method for charger noise rejection in a touch panel in accordance with the present invention;

FIG. 2 is a schematic front view of a sensing frame sensed by the driving method in FIG. 1;

FIG. 3 is a schematic front view of another sensing frame sensed by the driving method in FIG. 1;

FIG. 4 is a flow chart of a second embodiment of a driving method for charger noise rejection in a touch panel in accordance with the present invention;

FIG. 5 is a schematic front view of a sensing frame sensed by the driving method in FIG. 4;

FIG. 6 is a schematic side view of a conventional capacitive touch panel;

FIG. 7 is a schematic side view of the conventional capacitive touch panel in FIG. 6 touched by a finger and generating a new capacitor;

FIG. 8 is a circuit diagram illustrating a variation of capacitance value at the touched position of the conventional capacitive touch panel in FIG. 7; and

FIG. 9 is a schematic side view of a sensing frame of a mutual capacitance touch panel sensing capacitance values caused by charger noises at sensing points of the touch panel.

### DETAILED DESCRIPTION OF THE INVENTION

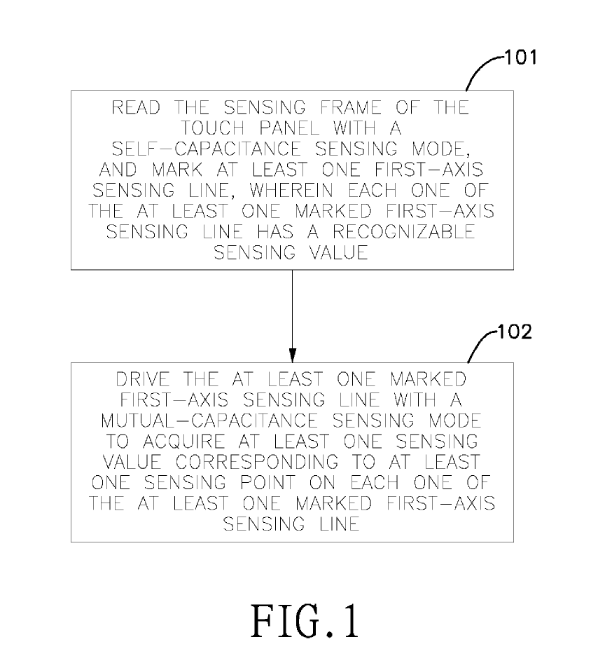

With reference to FIG. 1, a first embodiment of a driving method for charger noise rejection in a touch panel in accordance with the present invention drives a touch panel having multiple first-axis sensing lines and multiple second-axis sensing lines being perpendicularly crossed by and capacitively coupled to the first-axis sensing lines, and has the following steps:

Step 101: Read the sensing frame of the touch panel with a self-capacitance sensing mode, and mark at least one first-axis sensing line, wherein each one of the at least one marked first-axis sensing line has a recognizable sensing value.

Step 102: Drive the at least one marked first-axis sensing line with a mutual-capacitance sensing mode to acquire at least one sensing value corresponding to at least one sensing point on each one of the at least one marked first-axis sensing line.

As the self-capacitance sensing mode is good at its anti-interference capability against charger noise, when sensing lines are read by using the self-capacitance sensing mode and interference caused by charger noise occurs, no recognizable sensing value will appear, and only sensing values actually generated because of finger touch can be treated as recognizable sensing values. When the mutual-capacitance sensing mode is performed, the sensing lines to be driven are selected according to a result read by using the self-capacitance sensing mode. In other words, the result read under the self-capacitance sensing mode contains recognizable sensing values, and sensing lines having recognizable sensing values are selected and marked so as to get rid of interference arising from noise. Furthermore, as only the marked sensing lines are driven during the mutual-capacitance mode, a frame rate can be relatively enhanced.

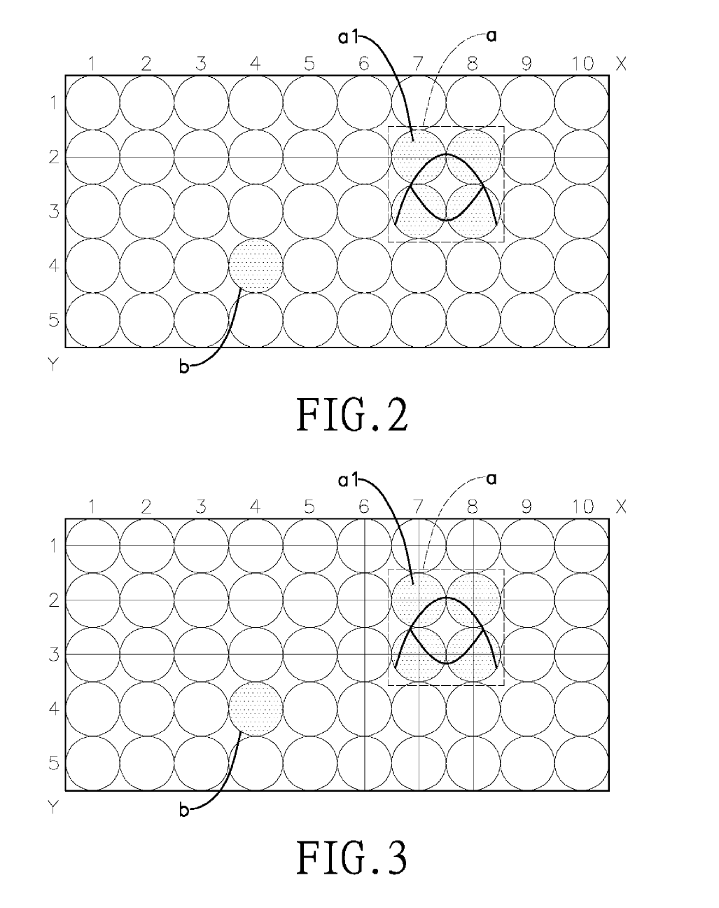

With reference to FIG. 2, multiple sensing lines and multiple sensing points of each sensing line on a sensing frame are shown. A sensing point group a circled on the right side of the sensing frame pertains to an actual position touched by a finger. As charger noise occurs when a device having a touch panel is being charged, a sensing value of a sensing point at coordinate (4, 4) is read under the mutual-capacitance sensing mode. The sensing point having the sensing value acquired under the mutual-capacitance sensing mode must be judged if the sensing value is a peak value before being reported. To be a peak value, a condition that a sensing value (dV value) of a corresponding sensing point is greater than the sensing value of each of four surrounding sensing points and also greater than a peak threshold (PeakTH), or is just greater than a peak threshold (PeakTH) should be fulfilled. According to the condition, a sensing point b and a sensing point al in the sensing point group a are both considered as peak values. Under the circumstance, if all sensing points are read by using the mutual-capacitance sensing mode, not only the sensing values of all the sensing points in the sensing point group a are considered as peak values and the coordinates of the sensing points in the sensing point group a are reported, but also the sensing value of the sensing point b is considered as a peak value and the coordinate of the sensing point b are reported. In the present invention the self-capacitance sensing mode is employed first to read each sensing line and set up a peak threshold. A result read along the first-axis sensing line (Y axis) has only a second Y-axis sensing line qualified for the condition. When the mutual-capacitance sensing mode is subsequently employed to read, basically, only the second Y-axis sensing line identified through the self-capacitance sensing mode is driven to acquire the sensing point group at the position touched by a finger. Since only the second Y-axis sensing line is driven, the sensing point b on the fourth Y-axis sensing line is not read and the coordinate of the sensing point b is not reported either, thereby effectively avoiding interference resulting from charger noise.

To ensure stability and accuracy of signals, when the mutual-capacitance sensing mode is employed to drive partial specific sensing lines, the sensing lines next to the sensing line having recognizable sensing values are simultaneously driven. For example, with reference to FIG. 3, when the second Y-axis sensing line having the recognizable sensing value is driven by the mutual-capacitance mode, the first and third Y-axis sensing lines are also driven.

After a specific first-axis sensing line is driven, multiple second-axis (X axis) sensing lines serve to receive the ADC raw data. A base value is subtracted from the ADC raw data to obtain sensing values of the X-axis sensing lines (dV value). Two following approaches are employed to read the X-axis sensing lines.

1. Total read option: Signals of all the X-axis sensing lines are read.

2. Partial read option: Signals of particular X-axis sensing lines are read.

The particular X-axis sensing lines denote the X-axis sensing lines having recognizable sensing values when the sensing frame is read under the self-capacitance sensing mode. Given FIG. 3 as an example, only the seventh X-axis sensing line is read, meaning that the sensing line having the recognizable value, namely, the seventh X-axis sensing line, and identified through the self-capacitance mode is read under the partial read option. To ensure signal accuracy, the X-axis sensing lines next to the seventh X-axis sensing line, namely, the sixth to eighth X-axis sensing lines, are also read.

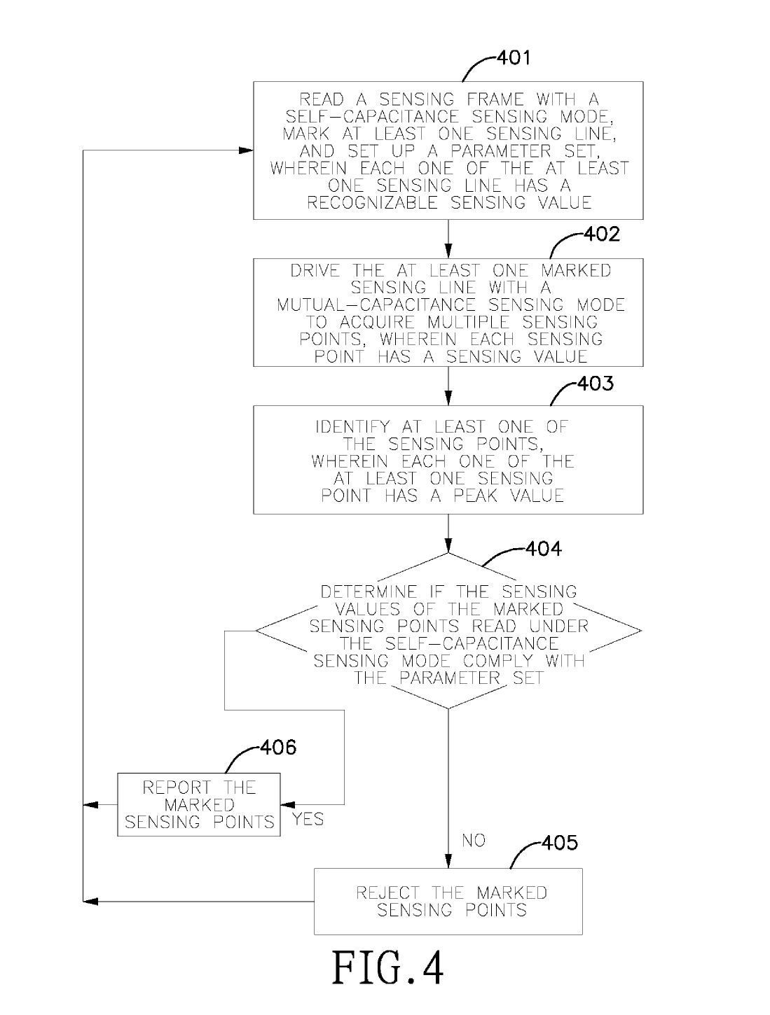

With reference to FIG. 4, a second embodiment of a driving method for charger noise rejection in a touch panel in accordance with the present invention has the following steps.

Step 401: Read a sensing frame with a self-capacitance sensing mode, mark at least one sensing line, and set up a parameter set, wherein each one of the at least one sensing line has a recognizable sensing value.

Step 402: Drive the at least one marked sensing line with a mutual-capacitance sensing mode to acquire multiple sensing points, wherein each sensing point has a sensing value.

Step 403: Identify at least one of the sensing points, each of which has a peak value from the sensing points, wherein the peak value is decided by determining whether the sensing value of the present sensing point is greater than the sensing values of four surrounding sensing points and also greater than a peak threshold (PeakTH), or just by determining whether the sensing value of the present point is greater than a peak threshold.

Step 404: Determine if the sensing values of the marked sensing points read under the self-capacitance sensing mode are greater than comply with the parameter set.

Step 405: If the sensing values of the marked sensing points read under the self-capacitance sensing mode are not greater than the parameter set, reject the marked sensing points.

Step 406: If the sensing values of the marked sensing points read under the self-capacitance sensing mode are grater than the parameter set, report the marked sensing points.

The parameter set configured under the self-capacitance sensing mode in the foregoing step particularly denotes an X-axis threshold and a Y-axis threshold set up with respect to the X axis and Y axis. In other words, the acquired sensing points under the mutual-capacitance sensing mode are marked, and the sensing values of the marked sensing points acquired under the self-capacitance sensing mode are further identified. The identified sensing values are further compared with the respective X-axis threshold and Y-axis threshold. Specifically, the sensing values, which are acquired under the self-capacitance sensing mode, of the sensing lines (marked sensing lines) on which the marked sensing points are located are identified. If the acquired sensing value of each marked sensing point under the self-capacitance sensing mode is greater than the X-axis threshold and the Y-axis threshold, the sensing value of the marked sensing point is reported. Otherwise, if the sensing value of each marked sensing point that is acquired under the self-capacitance sensing mode is not greater than either one of the X-axis threshold and the Y-axis threshold, the marked sensing point is rejected. The driving method of the present embodiment can more effectively eliminate false report of sensing point caused by charger noise.

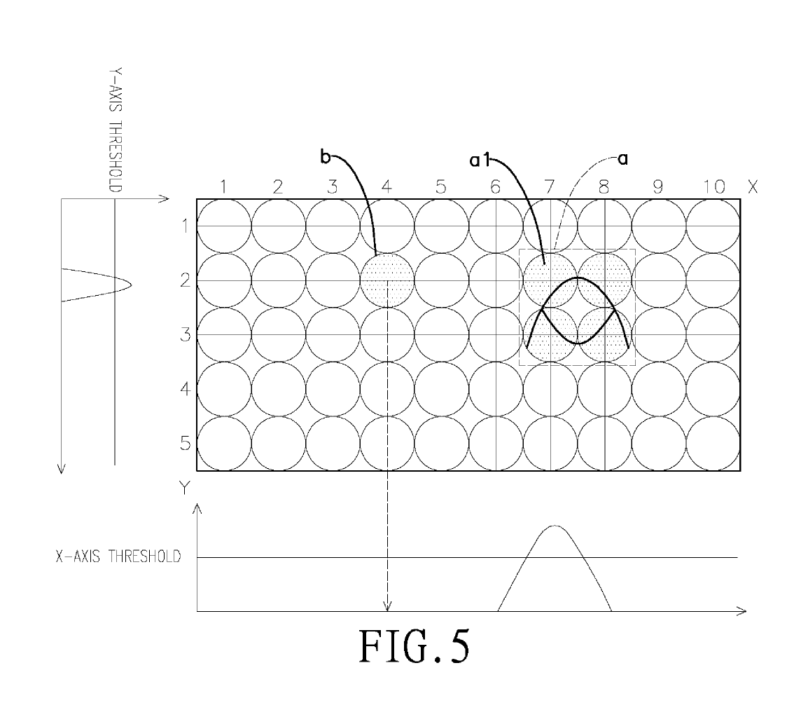

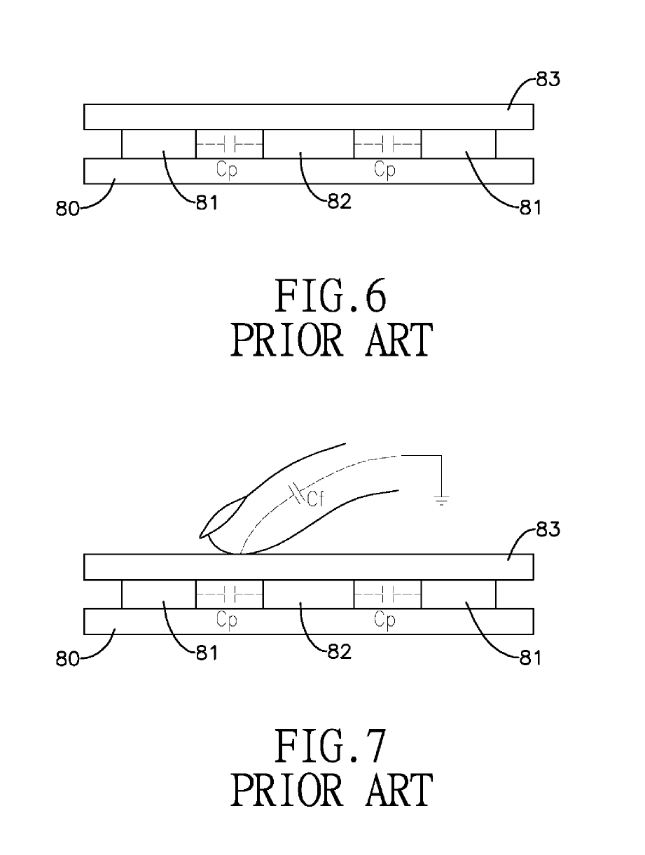

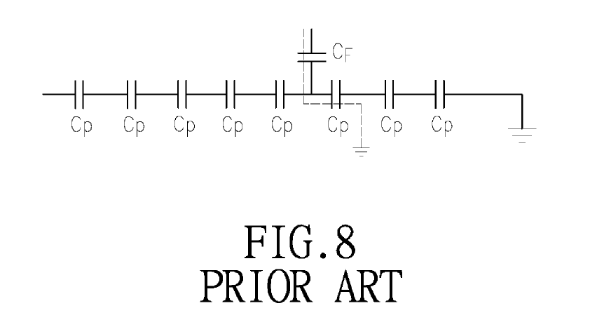

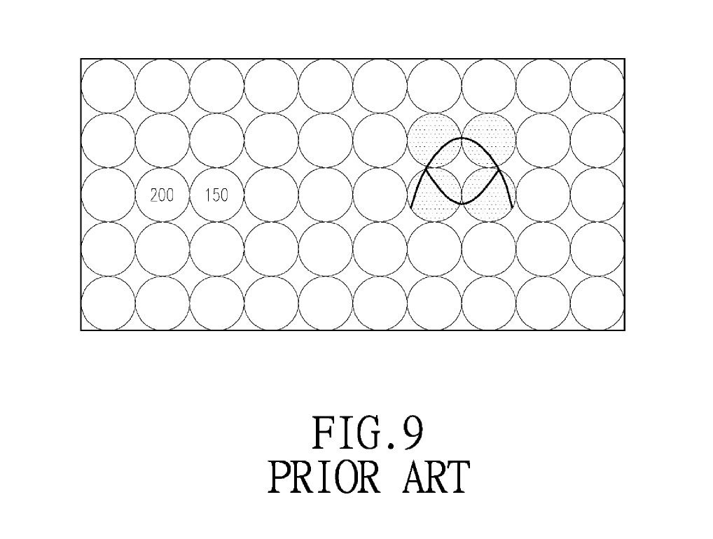

With reference to FIG. 5, the sensing lines and the corresponding sensing points acquired by the driving method of the present embodiment and respectively read under the self-capacitance sensing mode and the mutual-capacitance sensing mode are shown. A circled sensing point group a on the right side of FIG. 5 is also a position actually touched by a finger. The sensing point b on the left side of FIG. 5 is caused by charger noise. As the sensing point b and the sensing point group a are both located on the second Y-axis sensing line, the second Y-axis sensing line is surely driven when the Y-axis sensing lines are driven under the mutual-capacitance sensing mode. When the total read option is chosen to read the X-axis sensing lines, the sensing value of the sensing point b is acquired without exception. When the partial read option is chosen to read the X-axis sensing lines, the X-axis sensing line corresponding to the sensing point b is intentionally neglected and there is no way to read sensing value of the sensing point b. To cope with the misjudgment possibly caused upon the total read option, the embodiment disclosed in FIG. 4 can effectively eliminate such misjudgment.

When the sensing values of the fourth X-axis sensing line are acquired under the mutual-capacitance sensing mode, the acquired sensing values of the X-axis sensing line are further compared with the configured X-axis threshold and Y-axis threshold. As the self-capacitance sensing mode is good at its anti-interference capability against charger noise, the sensing values arising from charger noise are certainly lower than the X-axis threshold and the Y-axis threshold so that the sensing values of the sensing points arising from charger noise can be effectively ruled out. With reference to FIG. 5, two curve diagrams on the left side and lower side of the sensing frame respectively denote the Y-axis threshold and the X-axis threshold set up under the self-capacitance sensing mode. It is noted from FIG. 5 that the sensing point b arising from charger noise is located on the second Y-axis sensing line and the sensing value of the second Y-axis is greater than the Y-axis threshold. Since the sensing point group a touched by a finger is also located on the second Y-axis sensing line, the sensing value of the second Y-axis sensing line is greater than the Y-axis threshold. Upon determining if the sensing values on the X-axis sensing line are greater than the X-axis threshold, as the self-capacitance sensing mode is good at its anti-interference capability against charger noise, only the sensing values of the sensing points in the sensing point group a are greater than the X-axis threshold while the sensing value of the sensing point b is not greater than the X-axis threshold. Hence, the sensing point b is rejected. Based on the driving method of the present invention, when the sensing points generated due to finger touch and the sensing points caused by charger noise are on the same sensing line, the sensing points caused by charger noise can be effectively eliminated.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A driving method for charger noise rejection in a touch panel comprising steps of:
reading the sensing frame of the touch panel with a self-capacitance sensing mode, and marking at least one first-axis sensing line, wherein each one of the at least one marked first-axis sensing line has a recognizable sensing value; and
driving the at least one marked first-axis sensing line with a mutual-capacitance sensing mode to acquire at least one sensing value corresponding to at least one sensing point on each one of the at least one marked first-axis sensing line.

2. The driving method as claimed in claim 1, wherein
after the at least one marked first-axis sensing line is driven with the mutual-capacitance sensing mode, signals of all the second-axis sensing lines are read, and
the second-axis sensing lines are perpendicularly crossed by and capacitively coupled to the first-axis sensing lines.

3. The driving method as claimed in claim 1, wherein
when the sensing frame of the touch panel is read with the self-capacitance sensing mode, at least one of the second-axis sensing lines is marked, wherein each one of the at least one marked second-axis sensing line has a recognizable sensing value;
the second-axis sensing lines are perpendicularly crossed by and capacitively coupled to the first-axis sensing lines; and
after the at least one marked first-axis sensing line is driven with the mutual-capacitance sensing mode, signal of the at least one marked second-axis sensing line is read.

4. The driving method as claimed in claim 3, wherein the mutual-capacitance sensing mode is employed to read the at least one marked second-axis sensing line and the second-axis sensing lines next to each one of the at least one marked second sensing line.

5. The driving method as claimed in claim 1, wherein the mutual-capacitance sensing mode is employed to drive the at least one marked first-axis sensing line and the first-axis sensing lines next to each one of the at least one marked first-axis sensing line.

6. The driving method as claimed in claim 2, wherein the mutual-capacitance sensing mode is employed to drive the at least one marked first-axis sensing line and the first-axis sensing lines next to each one of the at least one marked first-axis sensing line.

7. The driving method as claimed in claim 3, wherein the mutual-capacitance sensing mode is employed to drive the at least one marked first-axis sensing line and the first-axis sensing lines next to each one of the at least one marked first-axis sensing line.

8. The driving method as claimed in claim 4, wherein the mutual-capacitance sensing mode is employed to drive the at least one marked first-axis sensing line and the first-axis sensing lines next to each one of the at least one marked first-axis sensing line.

9. The driving method as claimed in claim 1, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value is greater than the parameter set; and
if the sensing value acquired under the self-capacitance sensing mode of each sensing point having the peak value is not greater than the parameter set, rejecting the sensing point having the peak value.

10. The driving method as claimed in claim 2, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value is greater than the parameter set; and
if the sensing value acquired under the self-capacitance sensing mode of each sensing point having the peak value is not greater than the parameter set, rejecting the sensing point having the peak value.

11. The driving method as claimed in claim 3, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value is greater than the parameter set; and
if the sensing value acquired under the self-capacitance sensing mode of each sensing point having the peak value is not greater than the parameter set, rejecting the sensing point having the peak value.

12. The driving method as claimed in claim 4, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value is greater than the parameter set; and
if the sensing value acquired under the self-capacitance sensing mode of each sensing point having the peak value is not greater than the parameter set, rejecting the sensing point having the peak value.

13. The driving method as claimed in claim 9, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

14. The driving method as claimed in claim 10, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

15. The driving method as claimed in claim 11, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

16. The driving method as claimed in claim 12, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

17. The driving method as claimed in claim 13, wherein
in the step of determining if the sensing value of each sensing point has the peak value, the sensing value of each sensing point is determined to be greater than the sensing value of each of four surrounding sensing points; and
if the sensing value of each sensing point is greater than the sensing value of each of four surrounding sensing points, the sensing point has the peak value.

18. The driving method as claimed in claim 14, wherein
in the step of determining if the sensing value of each sensing point has the peak value, the sensing value of each sensing point is determined to be greater than the sensing value of each of four surrounding sensing points; and
if the sensing value of each sensing point is greater than the sensing value of each of four surrounding sensing points, the sensing point has the peak value.

19. The driving method as claimed in claim 15, wherein
in the step of determining if the sensing value of each sensing point has the peak value, the sensing value of each sensing point is determined to be greater than the sensing value of each of four surrounding sensing points; and
if the sensing value of each sensing point is greater than the sensing value of each of four surrounding sensing points, the sensing point has the peak value.

20. The driving method as claimed in claim 16, wherein
in the step of determining if the sensing value of each sensing point has the peak value, the sensing value of each sensing point is determined to be greater than the sensing value of each of four surrounding sensing points; and
if the sensing value of each sensing point is greater than the sensing value of each of four surrounding sensing points, the sensing point has the peak value.

21. The driving method as claimed in claim 13, wherein
in the step of determining if the sensing value of each sensing point has the peak value, the sensing value of each sensing point is determined to be greater than a peak threshold; and
if the sensing value of each sensing point is greater than the peak threshold, the sensing point has the peak value.

22. The driving method as claimed in claim 14, wherein
in the step of determining if the sensing value of each sensing point has the peak value, the sensing value of each sensing point is determined to be greater than a peak threshold; and
if the sensing value of each sensing point is greater than the peak threshold, the sensing point has the peak value.

23. The driving method as claimed in claim 15, wherein
in the step of determining if the sensing value of each sensing point has the peak value, the sensing value of each sensing point is determined to be greater than a peak threshold; and
if the sensing value of each sensing point is greater than the peak threshold, the sensing point has the peak value.

24. The driving method as claimed in claim 16, wherein
in the step of determining if the sensing value of each sensing point has the peak value, the sensing value of each sensing point is determined to be greater than a peak threshold; and
if the sensing value of each sensing point is greater than the peak threshold, the sensing point has the peak value.

25. The driving method as claimed in claim 5, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value is greater than the parameter set; and
if the sensing value acquired under the self-capacitance sensing mode of each sensing point having the peak value is not greater than the parameter set, rejecting the sensing point having the peak value.

26. The driving method as claimed in claim 6, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value is greater than the parameter set; and
if the sensing value acquired under the self-capacitance sensing mode of each sensing point having the peak value is not greater than the parameter set, rejecting the sensing point having the peak value.

27. The driving method as claimed in claim 7, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value complies with the parameter set; and
if the sensing value acquired under the self-capacitance sensing mode of each sensing point having the peak value does not comply with the parameter set, rejecting the sensing point having the peak value.

28. The driving method as claimed in claim 8, further comprising steps of:
setting up a parameter set under the self-capacitance sensing mode;
determining if the sensing value of each sensing point on each one of the at least one marked first-axis sensing line acquired under the mutual-capacitance sensing mode is a peak value;
determining if the sensing value acquired under the self-capacitance sensing mode of each sensing point having the peak value is greater than the parameter set; and
if the sensing value acquired under the self-capacitance sensing mode of each sensing point having the peak value is not greater than the parameter set, rejecting the sensing point having the peak value.

29. The driving method as claimed in claim 25, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

30. The driving method as claimed in claim 26, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

31. The driving method as claimed in claim 27, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

32. The driving method as claimed in claim 28, wherein
the parameter set is an X-axis threshold and a Y-axis threshold; and
if the sensing value of each marked sensing point acquired under the self-capacitance sensing mode is not greater than either one of the X-axis threshold and the Y-axis threshold, the sensing point having the peak value is rejected.

33. The driving method as claimed in claim 25, wherein
the sensing value of each sensing point is determined to be greater than the sensing value of each of four surrounding sensing points; and
if the sensing value of each sensing point is greater than the sensing value of each of four surrounding sensing points, the sensing point has the peak value.

34. The driving method as claimed in claim 26, wherein
the sensing value of each sensing point is determined to be greater than the sensing value of each of four surrounding sensing points; and
if the sensing value of each sensing point is greater than the sensing value of each of four surrounding sensing points, the sensing point has the peak value.

35. The driving method as claimed in claim 27, wherein
the sensing value of each sensing point is determined to be greater than the sensing value of each of four surrounding sensing points; and
if the sensing value of each sensing point is greater than the sensing value of each of four surrounding sensing points, the sensing point has the peak value.

36. The driving method as claimed in claim 28, wherein
the sensing value of each sensing point is determined to be greater than the sensing value of each of four surrounding sensing points; and
if the sensing value of each sensing point is greater than the sensing value of each of four surrounding sensing points, the sensing point has the peak value.

37. The driving method as claimed in claim 25, wherein
the sensing value of each sensing point is determined to be greater than a peak threshold; and
if the sensing value of each sensing point is greater than the peak threshold, the sensing point has the peak value.

38. The driving method as claimed in claim 26, wherein
the sensing value of each sensing point is determined to be greater than a peak threshold; and
if the sensing value of each sensing point is greater than the peak threshold, the sensing point has the peak value.

39. The driving method as claimed in claim 27, wherein
the sensing value of each sensing point is determined to be greater than a peak threshold; and
if the sensing value of each sensing point is greater than the peak threshold, the sensing point has the peak value.

40. The driving method as claimed in claim 28, wherein
the sensing value of each sensing point is determined to be greater than a peak threshold; and
if the sensing value of each sensing point is greater than the peak threshold, the sensing point has the peak value.
